(19) United States
(12) Patent Application Publication
(10) Pub. No.: US 2012/0167951 A1
(43) Pub. Date: Jul. 5, 2012

(54) SOLAR CELL MODULE, SOLAR POWER GENERATING APPARATUS, AND WINDOW

(75) Inventors: Tsuyoshi Maeda, Osaka (JP); Hideki Uchida, Osaka (JP)

(73) Assignee: Sharp Kavushiki Kaisha, Osaka (JP)

(21) Appl. No.: 13/496,459

(22) PCT Filed: Oct. 19, 2010
(86) PCT No.: PCT/JP2010/068382

§ 371 Date: Mar. 15, 2012

(30) Foreign Application Priority Data
Nov. 18, 2009 (JP) 2009-263022
Jun. 21, 2010 (JP) 2010-140719

(51) Int. Cl. H01L 31/052

(52) U.S. Cl. 136/246

(57) ABSTRACT

In order to realize a transparent solar cell module with a high design freedom, a solar cell module (10) includes a light guide plate (1) and a solar cell element (2). The light guide plate (1) includes, on its back surface opposite to its light entry surface, traveling direction changing sections (11) for changing a traveling direction of light incident via the light entry surface. Each of the traveling direction changing sections (11) includes a first inclined surface (11a) for reflecting the light incident via the light entry surface and a second inclined surface (11b). The solar cell element (2) is provided on, among intersecting surfaces which intersect with the light entry surface of the light guide plate (1), an end face that light reflected by the first inclined surface (11a) reaches.

### TECHNICAL FIELD

The present invention relates to a solar cell module, a solar power generating apparatus having the solar cell module, etc.

### BACKGROUND ART

With the aim of efficient utilization of solar energy, a generally-used conventional solar power generating apparatus is used with its solar panels laid all over its surface in such a way that the solar panels are directed toward the sun. Since such solar panels are made from an opaque semiconductor in general, the solar panels cannot be stacked. Therefore, it is necessary to employ large-area solar panels, in order to sufficiently converge solar light. This also requires a large installation area.

As a technique for efficiently utilizing solar energy while achieving a small area of solar panels, Patent Literature 1 discloses such a technique that a solar cell is provided on an end face of a fluorescent plate in which a fluorescent material is dispersed, so that solar light entering the fluorescent plate efficiently converges at the solar cell, thereby increasing power generation efficiency.

Further, each of Patent Literatures 2 and 3 discloses such a technique that a solar cell is provided on an end face of a wedge-shaped light guide plate so that light entering the light guide plate converges at the solar cell. Furthermore, Patent Literature 4 discloses such a technique that a solar cell is provided on an end face of a light guide plate having a series of curved shapes, so that light entering the light guide plate converges at the solar cell. As for Patent Literatures 2 and 4, light convergence efficiency is increased by painting white a surface which is opposite to a light entry surface or by providing a reflection film on the surface so that the surface serves as a reflecting surface.

### CITATION LIST

### Patent Literature

Patent Literature 1

Japanese Unexamined Utility Model Application Publication, Jitsukaisho No. 61-136559 U (Publication Date: Aug. 25, 1986)

Patent Literature 2

Japanese Patent Application Publication, Tokukaihei, No. 7-122771 A (Publication Date: May 12, 1995)

Patent Literature 3

Japanese Patent Application Publication, Tokukai, No. 2004-47752 A (Publication Date: Feb. 12, 2004)

Patent Literature 4

Japanese Patent Application Publication, Tokukaihei, No. 11-46008 A (Publication Date: Feb. 16, 1999)

### SUMMARY OF INVENTION

### Technical Problem

In the case of the technique of Patent Literature 1, there is no need to increase an area of a solar panel to converge solar light. However, manufacturing costs are high because employed is a substrate in which a large amount of fluorescent material is mixed. In addition, in a case where light which has entered a light absorbing-light emitting plate is totally reflected repeatedly therein, efficiency is decreased because the light abuts with the fluorescent material many times. Furthermore, the substrate is colored because the fluorescent material is dispersed in the substrate. Further, according to the techniques of Patent Literatures 2 through 4, the light guide plate has a wedge shape or a curved shape. Therefore, it is difficult to attach such a light guide plate to an existing window frame so as to use the light guide plate as a window glass. In particular, according to the techniques of Patent Literatures 2 and 4, a surface opposite to the light entry surface is a reflecting surface. Accordingly, such a light guide plate is not transparent and therefore not suitable for a use as a window glass. Furthermore, the light guide plate having a wedge shape converges light at its end. This leads to an extremely low light convergence in a case where the light guide plate has a large area. Thus, there is a difficulty in increasing an area of the light guide plate.

Therefore, sought after is a transparent solar cell module which is more inexpensive and easier to manufacture, and high in design freedom, while achieving space saving.

The present invention was made in view of the problems. An object of the present invention is to provide (i) a transparent solar cell module which is inexpensive and easy to manufacture, and high in design freedom, and (ii) a solar power generating apparatus or the like having the transparent solar cell module.

### Solution to Problem

In order to attain the object, a solar cell module of the present invention includes: a light guide plate having, on its back surface which is opposite to its light entry surface, traveling direction changing sections for changing a traveling direction of light incident via the light entry surface; and a solar cell element being provided on one of intersecting surfaces which intersects with the light entry surface of said light guide plate, the traveling direction changing sections each being a protruding or depressed structure having (i) a first inclined surface for reflecting the light incident via the light entry surface and (ii) a second inclined surface which forms an angle with the back surface, the angle is smaller than an angle formed between the first inclined surface and the back surface, and the one of the intersecting surfaces on which said solar cell element is provided is one of the intersecting surfaces to which the light reflected on the first inclined surface travels to reach.

According to the arrangement, the light which has entered a traveling direction changing section is reflected on its first inclined surface so as to converge at the solar cell element. This makes it possible to converge, at the solar cell element, more light entering the light guide plate. As a result, power generation efficiency is increased. Further, at least a part of light incident on a second inclined surface via the light entry surface passes through the second inclined surface having a less steep inclination than the inclination of the first inclined surfaces. This makes it possible to maintain the transparency of the light guide plate. This makes it possible to realize a transparent solar cell module which can efficiently generate electricity. Such a transparent solar cell module can be attached to, e.g., an existing window frame so as to be suitably used as a window glass.

Each of the traveling direction changing sections is the depressed structure or the depressed structure. In any case, the solar cell element is provided on that one of the intersecting surfaces which is located in a direction in which the first inclined surfaces reflect, toward the inside of the light guide plate, light incident via the light entry surface (in a direction in which the first inclined surfaces faces the inside of the light guide plate).

A solar power generating apparatus of the present invention includes any one of the solar cell modules. The solar cell module is a transparent one, and is high in design freedom, and inexpensive and easy to manufacture, with maintenance of a sufficient power generation efficiency. Therefore, a solar power generating apparatus having the solar cell module is suitably applicable to a photovoltaic power system in a window of a building or an automobile, or a photovoltaic power system on a roof of a building.

### Advantageous Effects of Invention

A solar cell module of the present invention includes: a light guide plate having, on its back surface which is opposite to its light entry surface, traveling direction changing sections for changing a traveling direction of light incident via the light entry surface; and a solar cell element being provided on one of intersecting surfaces which intersects with the light entry surface of said light guide plate, the traveling direction changing sections having (i) a first inclined surface for reflecting the light incident via the light entry surface and (ii) a second inclined surface, the one of the intersecting surfaces on which said solar cell element is provided is one of the intersecting surfaces to which the light reflected on the first inclined surface travels to reach. This makes it possible to manufacture a transparent solar cell module with a high design freedom easily and inexpensively.

### BRIEF DESCRIPTION OF DRAWINGS

FIG. 1 is a cross-sectional view illustrating a solar cell module of one embodiment of the present invention.

FIG. 2 is a perspective view illustrating the solar cell module of the one embodiment of the present invention.

FIG. 3 is a schematic view illustrating the solar cell module of the one embodiment of the present invention.

FIG. 4 is a cross-sectional view illustrating a solar cell module of another embodiment of the present invention.

FIG. 5 is a cross-sectional view illustrating the solar cell module of another embodiment of the present invention.

FIG. 6 is a cross-sectional view illustrating a solar cell module of another embodiment of the present invention.

FIG. 7 is a cross-sectional view illustrating a solar cell module of another embodiment of the present invention.

FIG. 8 is a cross-sectional view illustrating a solar cell module of another embodiment of the present invention.

FIG. 9 is a cross-sectional view illustrating a solar cell module of another embodiment of the present invention.

FIG. 10 is a cross-sectional view illustrating a solar cell module of another embodiment of the present invention.

FIG. 11 is a perspective view illustrating a solar cell module of another embodiment of the present invention.

FIG. 12 is a perspective view illustrating a solar cell module of another embodiment of the present invention.

FIG. 13 is a cross-sectional view illustrating a solar cell module of another embodiment of the present invention.

FIG. 14 is a cross-sectional view illustrating a solar cell module of another embodiment of the present invention.

FIG. 15 is a cross-sectional view illustrating a solar cell module of another embodiment of the present invention.

### DESCRIPTION OF EMBODIMENTS

### Embodiment 1

(Solar Cell Module 10)

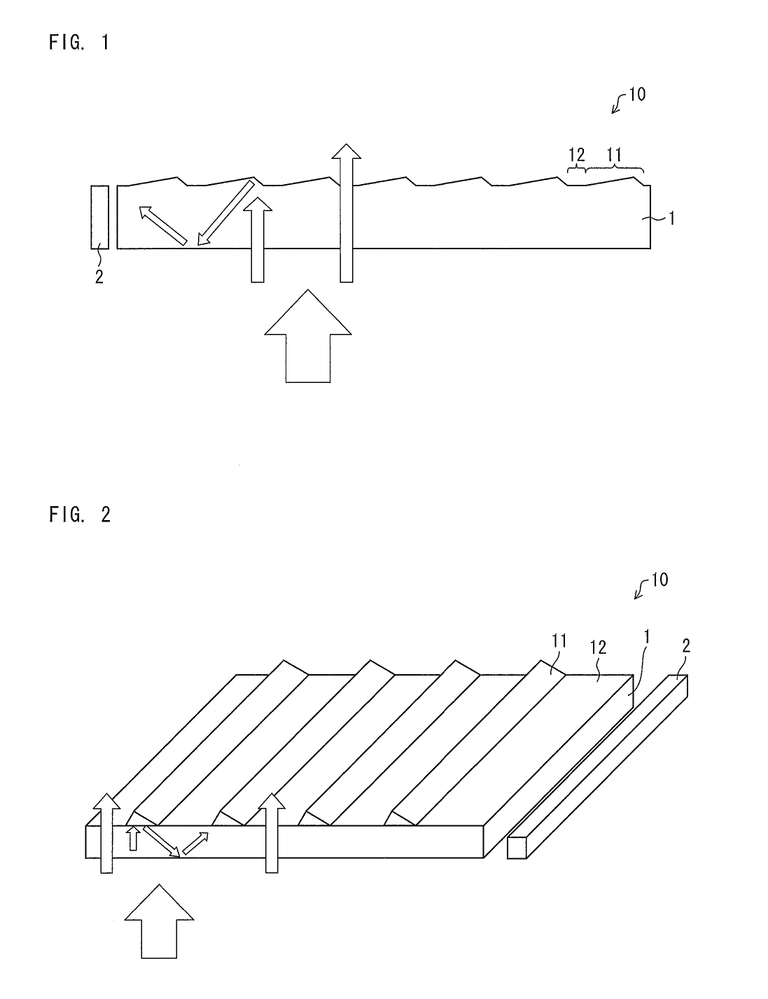

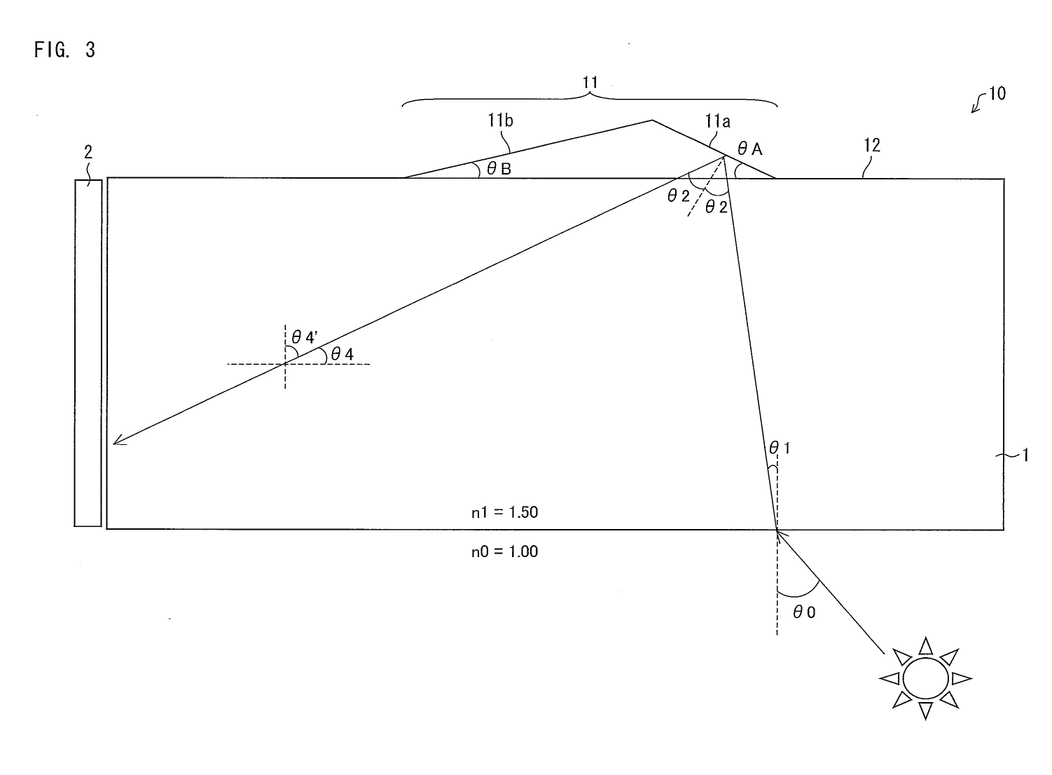

The following describes one embodiment of a solar cell module of the present invention, with reference to FIGS. 1 through 3. FIG. 1 is a cross-sectional view illustrating a solar cell module 10. FIG. 2 is a perspective view illustrating the solar cell module 10. FIG. 3 is a schematic view for explaining the solar cell module 10.

As illustrated in FIGS. 1 through 3, the solar cell module 10 includes a light guide plate 1 and a solar cell element 2. In addition, provided on that back surface of the light guide plate 1 which is opposite to a light entry surface indicated by the arrows are (i) traveling direction changing sections 11 for changing a traveling direction of light which has entered the light guide plate 1 via the light entry surface and (ii) transmission sections 12 for allowing light to pass therethrough which has entered the light guide plate 1 via the light entry surface.

Each of the traveling direction changing sections 11 includes (i) a first inclined surface 11a which totally reflects light which has entered the light guide plate 1 via the light entry surface and (ii) a second inclined surface 11b which is inclined in a direction opposite to a direction in which the first inclined surface 11a is inclined. An angle θB which is formed between the second inclined surface 11b and the back surface is smaller than an angle θA which is formed between the first inclined surface 11a and the back surface. The solar cell element 2 is provided on, out of those intersecting surfaces of the light guide plate 1 which intersect with the light entry surface, an intersecting surface which is located on a second inclined surface 11b side with respect to the first inclined surface 11a. Although for convenience of explanation, FIGS. 1 through 3 illustrate the solar cell module 10 so that the solar cell element 2 is spaced from the intersecting surface of the light guide plate 1, the solar cell element 2 is actually provided so as to have a direct contact with the intersecting surface. The arrows in FIGS. 1 through 3 indicate light guiding and transmission directions of light. The same holds for other figures.

(Light Guide Plate 1)

The light guide plate 1 may be any plate, provided that the plate guides the light which has entered via the light entry surface, so as to converge the light at the solar cell element 2 which is provided on the end face. A conventional light guide plate may be employed as such a light guide plate 1. Examples of the conventional light guide plate encompass an acrylic substrate, a glass substrate, and a polycarbonate substrate. However, the light guide plate 1 is not limited thereto. A thickness of the light guide plate 1 is not particularly limited. The thickness is preferably not smaller than a wavelength of visible light, that is, not smaller than 1 μm. In consideration of a weight of the light guide plate 1 and an area of the solar cell to be provided on the end face, the thickness is preferably not greater than 10 cm.

The light guide plate 1 is for guiding therein the light which has entered the light guide plate 1. Therefore, the light guide plate 1 is preferably a transparent plate-like member which does not contain any fluorescent material. However, the light guide plate 1 may be any plate, provided that in a manufacturing process, the plate is not subjected to a process of dispersing a fluorescent material or the like which process is aimed at wavelength conversion inside the light guide plate 1. That is, it is possible to suitably use a light guide plate 1 which partially contains a fluorescent material without the intent of the wavelength conversion inside the light guide plate 1, and which is therefore not completely transparent.

In a case where the solar cell module 10 is attached to a window frame of building when used, employed as the light guide plate 1 is an acrylic substrate or the like which has such a size and a thickness that the light guide plate 1 can be attached to the window frame and can function as a window pane. In a case where the solar cell module 10 is provided on a roof when used, a size and a thickness of the light guide plate 1 are appropriately determined according to various conditions such as installation area. In a case where the light guide plate 1 is used as a window glass, the light guide plate 1 preferably has a cuboidal shape so as to be attachable to an existing window frame. However, the light guide plate 1 may have a wedge shape.

(Traveling Direction Changing Section 11)

The traveling direction changing sections 11 provided on the back surface change a traveling direction of light which has entered the light guide plate 1 via the light entry surface, so that the light converges at the solar cell element 2 provided on the end face. In FIGS. 1 through 3, the traveling direction changing sections 11 are provided so as to protrude from the back surface of the light guide plate 1 (that is, each of the traveling direction changing sections 11 is protruding). As illustrated in FIG. 2, the plurality of traveling direction changing sections 11 each having a triangular column shape extended in parallel with the intersecting surfaces of the light guide plate 1 are provided on the back surface so as to be arranged in a stripe pattern.

The first inclined surfaces 11a of the traveling direction changing sections 11 are reflecting surfaces which reflect, preferably totally, light which is incident upon the first inclined surfaces 11a via the light entry surface, and the first inclined surfaces 11a are surfaces inclined at the angle θA with respect to the back surface. The light incident upon the first inclined surfaces 11a is reflected thereon so as to be guided inside the light guide plate 1 toward the solar cell element 2, thereby converging at the solar cell element 2. The second inclined surfaces 11b are surfaces inclined at the angle θB with respect to the back surface. Since θB<θA, the inclination of the second inclined surfaces 11b is less steep than that of the first inclined surfaces 11a. The plurality of traveling direction changing sections 11 provided on the back surface of the solar cell module 10 are prism-shaped protrusions identical in shape and are provided so that the first inclined surfaces 11a are oriented in a same direction and the second inclined surfaces 11b are oriented in a same direction.

By thus providing the second inclined surfaces 11b, light reflected on the first inclined surfaces 11a can be guided inside the light guide plate 1 without being not incident upon, and therefore, not scattered by the second inclined surfaces 11b, so as to be converged at the solar cell element 2. That is, θA is set to an angle which makes it possible to reflect the light which has entered the light guide plate 1 via the light entry surface, and θB is set to an angle smaller than θA so that the light reflected on the first inclined surfaces 11a is not incident upon the second inclined surfaces 11b. An inclination angle of the first inclined surfaces 11a is different from that of the second inclined surfaces 11b. Each of the traveling direction changing sections 11 has a triangular cross-section along a plane perpendicular to the back surface and the intersecting surfaces. Each of the traveling direction changing sections 11 protrudes from the back surface so as to have an asymmetric shape.

In the solar cell module 10 illustrated in FIG. 3, solar light entering, at an angle θ0, the light entry surface is incident upon the first inclined surface 1 la so as to be totally reflected at an angle θ2 with respect to a normal to the first inclined surface 11a. The light totally reflected on the first inclined surface 11a is guided at an angle θ4′ with respect to a normal to a plane parallel with the light entry surface, and is totally reflected repeatedly inside the light guide plate 1 so as to reach the solar cell element 2. In a case where e.g.: θA is 24°; θB is 5°; a refractive index of the light guide plate 1 is 1.5; and an incident angle θ0 of the solar light is not smaller than 27°, θ2 is not smaller than 41° because a refractive index of the air is 1.0. The light totally reflected at such an angle θ2 on the first inclined surface 11a is totally reflected repeatedly inside the light guide plate 1 so as to reach the solar cell element 2. Thus, θA and θB are determined according to an angle of light entering the light guide plate 1 and a refractive index of the light guide plate 1.

The traveling direction changing sections 11 are made from a material which is the same as that of the light guide plate 1. The traveling direction changing sections 11 can be formed by cutting the back surface of the light guide plate 1. The traveling direction changing sections 11 may also be formed in such a manner that the material for the light guide plate 1 is put and cured in a die with which the traveling direction changing sections 11 having a predetermined shape can be formed on the light guide plate 1. The traveling direction changing sections 11 may be formed so as to protrude from the back surface of the light guide plate 1, or may be formed so as to be depressed from the back surface. In a case where the traveling direction changing sections 11 are formed so as to be depressed from the back surface, depressions each having the first inclined surface 11a and the second inclined surface 11b are formed under the aforementioned conditions.

(Transmission Section 12)

The transmission sections 12 provided on the back surface of the light guide plate 1 allow the light which has entered the light guide plate 1 via the light entry surface to pass through. Each of the transmission sections 12 is a flat area which allows light to pass through, and corresponds to that area on the back surface in which no traveling direction changing section 11 is provided. That is, the transmission sections 12 are identical with planes forming the back surface of the light guide plate 1. Simultaneously with the formation of the traveling direction changing sections 11 on the back surface of the light guide plate 1, the transmission sections 12 are formed as areas where no traveling direction changing section 11 is provided.

Since a part of the light which has entered the light guide plate 1 passes through the transmission sections 12, the light guide plate 1 looks nearly transparent when viewed from above the back surface. This makes it possible to use the light guide plate 1 of the solar cell module 10 as a window glass for example. This makes it possible to generate electricity efficiently from the solar light entering the light guide plate 1. In the present Specification, the word “transparent” denotes not only such a state that an object behind the light guide plate 1 can be seen as it is, but also such a state that an object behind the light guide plate 1 can be recognized although the light guide plate 1 can be recognized. The light guide plate 1 of the solar cell module 10 contains no fluorescent material or the like. Therefore, an object behind the light guide plate 1 does not look colored. Thus, the light guide plate 10 has high transparency.

(Solar Cell Element 2)

A conventional solar cell may be employed as the solar cell element 2. Examples of such a conventional solar cell encompass an amorphous silicon (a-Si) solar cell, a polycrystalline silicon solar cell, a monocrystalline silicon solar cell, and a compound solar cell. However, the solar cell element 2 is not limited thereto. With the use of a conventional light transmissive adhesive, fastener, or the like, the solar cell element 2 is attached to that surface of the light guide plate 1 which intersects with the light entry surface. A size of the solar cell element 2 is not particularly limited. However, a width of a light-receiving section of the solar cell element 2 is preferably equal to a thickness of the light guide plate 1. This makes it possible to efficiently receive light which has reached a side surface of the light guide plate 1 after being guided therein. Also, the number of the solar cell elements 2 is not particularly limited.

In a case where the solar cell module 10 is attached to a window frame when used, the solar cell module 10 is installed so that the solar cell element 2 is positioned below the window frame. This allows the solar light entering the light guide plate 1 to satisfy a reflection condition. As a result, the solar light is efficiently guided inside the light guide plate 1 so as to converge at the solar cell element 2. In this case, the solar cell module 10 is installed so that the light entry surface of the light guide plate 1 faces outward and the back surface faces inward.

The solar cell module 10 as illustrated in FIGS. 1 through 3 was produced to examine the power generation efficiency thereof. First, a transparent acrylic plate was made which had a size of 1 m×1 m and a thickness of 10 mm. Provided on one surface (back surface) of the acrylic plate were the protruding traveling direction changing sections 11 each having an asymmetric triangular cross-section. The solar cell element 2 was provided on an intersecting surface which is one on the second inclined surface 11b side out of intersecting surfaces intersecting with the surface on which the traveling direction changing sections 11 were provided.

The traveling direction changing sections 11 were formed so as to be arranged at an intersecting angle of 25° with respect to the intersecting surface and at a pitch of 300 μm. Further, the solar cell module 10 was arranged such that: an angle θA formed between the first inclined surfaces 11a and the back surface falls within a range of not smaller than 40.6° but not greater than 41.6°; an angle θB formed between the second inclined surfaces 11b and the back surface falls within a range of not less than 0.9° but not greater than 1.6°; a difference between respective inclination angles of two adjacent second inclined surfaces 11b falls within 0.1°; each of the first inclined surfaces 11a has a width of not smaller than 12.5 μm but not greater than 14.5 μm when projected on the light entry surface; and an area ratio of a first inclined surface 11a to a second inclined surface 11b is not greater than 1/20 when projected on the light entry surface. The traveling direction changing section 11 closest to the intersecting surface was spaced by 2 mm from the intersecting surface.

The surface of the solar cell module 10 thus made on which no traveling direction changing section 11 was provided was irradiated with the solar light. As a result, the solar cell module 10 generated an electricity of approximately 30 W. On the other hand, a conventional solar cell module having the same area was directly irradiated with the solar light. As a result, the conventional solar cell module generated an electricity of approximately 15 W. As described above, the solar cell module 10 includes, on the back surface of the light guide plate 1, the traveling direction changing sections 11 and the transmission sections 12. Accordingly, the light which has entered the light guide plate 1 via the light entry surface can be efficiently guided inside the light guide plate 1 so as to converge at the solar cell element 2. This makes it possible to efficiently generate electricity. Further, the light passes through the transmission sections 12. Thus, the light guide plate 1 has transparency across the light entry surface and the back surface. Therefore, the solar cell module 10 is suitably attached to a window frame of a building or an automobile when used. Further, the solar cell module 10 may also be attached onto a roof in the form of a roof tile or a skylight. This makes it possible to realize a highly-efficient photovoltaic power system. Furthermore, the solar cell element 2 is provided on a surface intersecting with the light entry surface of the light guide plate 1. This makes it possible to achieve a sufficient power generation efficiency with a small area of the solar cell element 2, and to also manufacture the solar cell module 10 at low costs.

The number and interval of the traveling direction changing sections 11 to be provided on the back surface is not particularly limited. However, a smaller interval and a greater area ratio of the traveling direction changing sections 11 to the transmission sections 12 make it possible to converge a greater amount of light at the solar cell element 2. In this case, a higher power generation efficiency is achieved. In contrast, a greater interval and a smaller ratio of the traveling direction changing sections 11 to the transmission sections 12 make it possible to secure the transparency of the light guide plate 1. In this case, the solar cell module 10 is used in combination with a window glass or the like more suitably.

Further, an infrared absorption agent or an infrared reflecting agent may be dispersed in the light guide plate 1. This makes it possible to effectively filter out infrared rays which cause rise in room temperature in a case where the solar module 10 is attached to a window frame so as to be used as a window glass. In a case where, e.g., the light guide plate 1 was made by dispersing, by 1 wt %, aluminum nitride particles as an infrared absorbing agent in the transparent acrylic plate made as described above, it was possible to filter out approximately 80% of infrared rays having a wavelength of 800 mm. It is also possible to obtain the same effect by providing an infrared reflecting layer on one or both sides of the transparent acrylic plate. Examples of such an infrared reflecting layer encompass a cholesteric liquid crystal layer and a dielectric multilayer. However, the infrared reflecting layer is not limited thereto.

(Solar Power Generating Apparatus)

A solar power generating apparatus of the present invention includes the solar cell module 10. The solar power generating apparatus of the present invention may include, e.g., a plurality of solar cell modules 10 and a storage battery for storing output power therefrom. Since the solar power generating apparatus of the present invention thus includes the solar cell module 10, the solar power generating apparatus can efficiently convert solar energy into electricity when used in combination with a window or a roof of a building, a window of an automobile, or the like.

### Embodiment 2

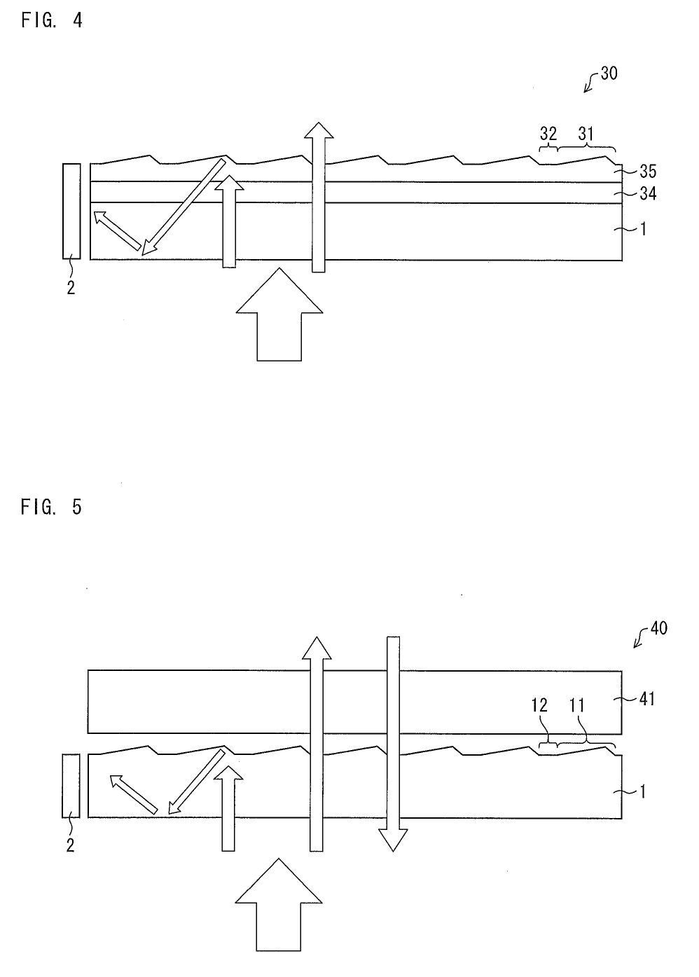

The following describes another embodiment of the solar cell module of the present invention, with reference to FIG. 4. FIG. 4 is a cross-sectional view illustrating a solar cell module 30. As illustrated in FIG. 4, the solar cell module 30 is different from the solar cell module 10 of Embodiment 1 in that a light transmissive film (membrane) 35 having traveling direction changing sections 31 and transmission sections 32 is attached onto the light guide plate 1. The present embodiment deals with only differences between the present embodiment and Embodiment 1, and omits to describe other details.

The solar cell module 30 is arranged such that the light transmissive film 35 is attached via an adhesive layer 34 on the back surface of the light guide plate 1. The light transmissive film 35 has the traveling direction changing sections 31 and the transmission sections 32 on its surface. That is, the traveling direction changing sections 31 and the transmission sections 32 are provided on the light transmissive film 35 which is provided on the back surface of the light guide plate 1.

The traveling direction changing sections 31 and the transmission sections 32 are provided in the same way as the traveling direction changing sections 11 and the transmission sections 12. Accordingly, each of the traveling direction changing sections 31 has a first inclined surface and a second inclined surface. A laminate made up of the light guide plate 1, the adhesive layer 34, and the light transmissive film 35 has intersecting surfaces which intersect with the back surface. A solar cell element 2 is provided on one of the intersecting surfaces which is located on a second inclined surface side. Further, each of the transmission sections 32 has a flat plane which is parallel with the back surface.

(Light Transmissive Film 35)

The light transmissive film 35 may be any film, provided that the film is made from a material which allows incident light to pass through. Examples of such a light transmissive film 35 encompass films made from an acrylic resin, a polypropylene resin, a cycloolefin resin, a polycarbonate resin, a triacetylcellulose resin, and a PET resin. However, the light transmissive film 35 is not limited thereto. The light transmissive film 35 is such a film that the traveling direction changing sections 31 which are projections or depressions and the transmission section 32 are provided on one surface of a film made from a resin material such as those mentioned above.

The light transmissive film 35 can be formed in such a manner that the resin material is stamped by use of a stamper for shaping the traveling direction changing sections 31 and the transmission sections 32, and then, the resin material thus shaped is cured. The light transmissive film 35 preferably has a thickness of not smaller than 10 μm but not greater than 1000 μm, or more preferably, not less than 20 μm but not greater than 200 μm. Accordingly, the light transmissive film 35 has a thickness which is suitable for being attached to the light guide plate 1. This makes it possible to easily attach the light transmissive film 35 to the light guide plate 1.

(Adhesive Layer 34)

The adhesive layer 34 is a layer made by forming a light transmissive adhesive into a layer, and can be made from a conventional adhesive. For example, a conventional acrylic adhesive can be employed as a material for the adhesive layer 34. However, the material is not limited thereto. Examples of suitable adhesives encompass α-olefin adhesives, urethane resin adhesives, epoxy resin adhesives, ethylene-vinyl acetate resin adhesives, and silicon adhesives.

The adhesive layer 34 can be formed in such a manner that an adhesive such as those mentioned above is applied onto the light guide plate 1 or the light transmissive film 35 so as to be in layers, and the light guide plate 1 and the light transmissive film 35 are attached to each other. In this case, the adhesive layer 34 preferably has a thickness of not smaller than 1 μm but not greater than 1000 μm, or more preferably, not smaller than 10 μm but not greater than 100 μm. This makes it possible to attach the light transmissive film 35 to the light guide plate 1 without intrusion of air bubbles.

The solar cell module 30 is arranged such that a relationship between a refractive index n(a) of the adhesive layer 34 and a refractive index n(s) of the light guide plate 1 satisfies: n(a)≦n(s). More preferably, the refractive index n(s) of the light guide plate 1 is greater than the refractive index n(a) of the adhesive layer 34. The solar cell module 30 may be arranged such that a relationship among the refractive index n(s) of the light guide plate 1, the refractive index n(a) of the adhesive layer 34, and a refractive index n(f) of the light transmissive film 35 satisfies: n(f)≦n(a)≦n(s). Accordingly, after light which has entered the light guide plate 1 via the light entry surface is reflected on the traveling direction changing sections, reflection of the light on an interface between the adhesive layer 34 and the light transmissive film 35 can suppressed, and further, total reflection of the light on an interface between the light guide plate 1 and the adhesive layer 34 does not occur, while the light is guided inside the light guide plate 1. This makes it possible to efficiently guide the light incident upon the traveling direction changing sections 31 so as to converge the light at the solar cell element 2. Further, the transmission section 32 allow incident light to pass through. This makes it possible to realize a transparent solar cell module 30.

As described above, the traveling direction changing sections 31 and the transmission sections 32 are provided on the back surface of the light guide plate 1 by attaching, to the back surface, the light transmissive film 35 having the traveling direction changing sections 31 and the transmission sections 32. Therefore, there is no need to form the traveling direction changing sections 31 and the transmission sections 32 in the formation of the light guide plate 1. Thus, the solar cell module 30 can be made in such a manner that the light transmissive film 35 is attached to a window glass or an acrylic plate, and the solar cell element 2 is attached then. Furthermore, the light transmissive film 35 may be freely patterned so as to be attached to the light guide plate 1.

### Embodiment 3

The following describes another embodiment of the solar cell module of the present invention, with reference to FIG. 5. FIG. 5 is a cross-sectional view illustrating a solar cell module 40. As illustrated in FIG. 5, the solar cell module 40 is different from the solar cell module 10 of Embodiment 1 in that a light transmissive substrate 41 is provided so as to face the back surface of the light guide plate 1. The present embodiment deals with only differences between the present embodiment and Embodiment 1, and omits to describe other details.

The solar cell module 40 includes the light transmissive substrate 41 which is stacked on the back surface of the light guide plate 1 so as to face thereto. The light transmissive substrate 41 is a substrate for allowing incoming light from the light guide plate 1 to pass through, and is a plate-like member made from a material which is the same as that of the light guide plate 1. The light transmissive substrate 41 has a surface which faces the back surface of the light guide plate 1 and a back surface which is opposite to the surface above, and these surfaces are flat planes. The light guide plate 1 and the light transmissive substrate 41 of the solar cell module 40 can be stacked by a method such as bonding the light guide plate 1 and the light transmissive substrate 41 via an light transmissive adhesive or the like.

In the solar cell module 40, the light transmissive substrate 41 covers that surface of the light guide plate 1 on which the traveling direction changing sections 11 and the transmission sections 12 are provided. Accordingly, the traveling direction changing sections 11 and the transmission sections 12 are protected by the light transmissive substrate 41. This makes it possible to prevent a flaw by contact etc. Further, the solar cell module 40 can be realized as a double-glazed glass. This makes it possible to realize a highly-efficient photovoltaic power system, and furthermore, to use such a solar cell module 40 as a window glass with a good thermal insulating property. Besides, it is possible to increase strength of the solar cell module 40 which is used as a window glass.

### Embodiment 4

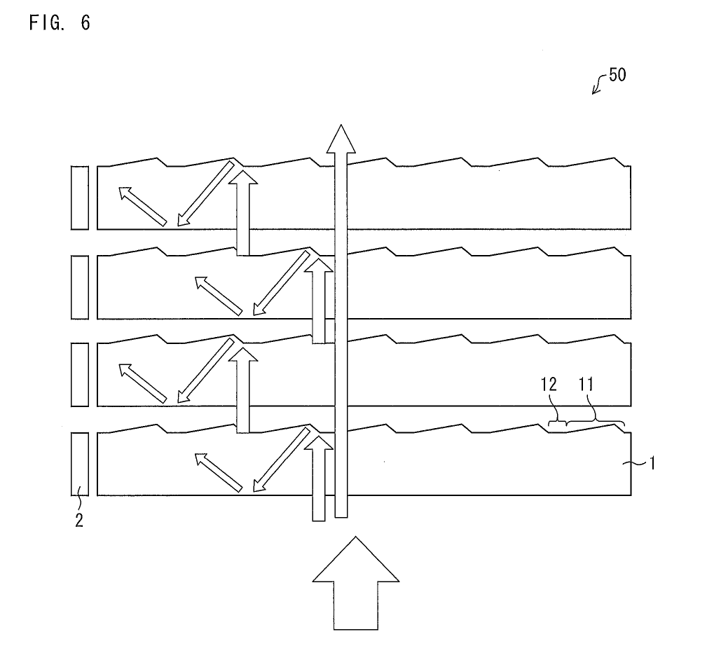

The following describes another embodiment of the solar cell module of the present invention, with reference to FIG. 6. FIG. 6 is a cross-sectional view illustrating a solar cell module 50. As illustrated in FIG. 6, the solar cell module 50 is different from the solar cell module 10 of Embodiment 1 in that a plurality of light guide plates 1 are provided, and the plurality of light guide plates 1 are stacked so that the back surface of a lower one of two adjacent light guide plates 1 faces the light entry surface of an upper one of the two adjacent light guide plates 1. The present embodiment deals with only differences between the present embodiment and Embodiment 1, and omits to describe other details.

The solar cell module 50 includes four light guide plates 1 and solar cell elements 2 which are provided so as to positionally correspond respectively to the four light guide plates 1. The plurality of light guide plates 1 are stacked so that the back surface of a lower one of two adjacent light guide plates 1 faces the light entry surface of an upper one of the two adjacent light guide plates 1. That is, the plurality of light guide plates 1 face in the same direction. Accordingly, the solar cell elements 2 of the light guide plates 1 are arranged in a line along the direction in which the light guide plates 1 area stacked. The plurality of light guide plates 1 of the solar cell module 50 can be stacked by a method such as bonding the plurality of light guide plates 1 via an light transmissive adhesive or the like.

The solar cell module 50 thus includes the plurality of stacked light guide plates 1. This makes it possible to efficiently generate electricity without increasing installation area. The solar cell module 50 illustrated in FIG. 6 was made to see how much electricity is generated by the solar cell module 50. The result was approximately 100 W.

Further, the solar cell module 50 may be arranged such that the traveling direction changing sections 11 of the plurality of light guide plates 1 are provided at a same interval so as to be in identical shapes, and the traveling direction changing sections 11 and the transmission sections 12 are provided in positions which are common among the plurality of stacked light guide plates 1. That is, the traveling direction changing sections 11 and the transmission sections 12 are in positions which are common among the plurality of light guide plates 1, and when the plurality of light guide plates 1 are viewed in a direction along a line penetrating the light entry surfaces and the back surfaces, the traveling direction changing sections 11 and the transmission sections 12 look overlapped across the plurality of light guide plates. This makes it possible to secure the transparency of the solar cell module 50.

Alternatively, the plurality of light guide plates 1 may be stacked so that the positions of the traveling direction changing sections 11 and the transmission sections 12 are displaced among the plurality of light guide plates 1 when the plurality of light guide plates 1 are viewed in the direction along a plane penetrating the light entry surfaces and the back surfaces. That is, the traveling direction changing sections 11 and the transmission sections 12 may be provided in positions which are different among the plurality of stacked light guide plates 1. Accordingly, even light which has entered the first light guide plate 1 via its light incident surface and exited from the back surface can be totally reflected on the back surface of the second or latter light guide plate 1 so as to converge at the solar cell element 2. This makes it possible to increase power generation efficiency of the solar cell elements 2.

The present embodiment deals with, as an example, the solar cell module 50 having the four light guide plates 1. However, the number of the light guide plates 1 is not limited thereto.

### Embodiment 5

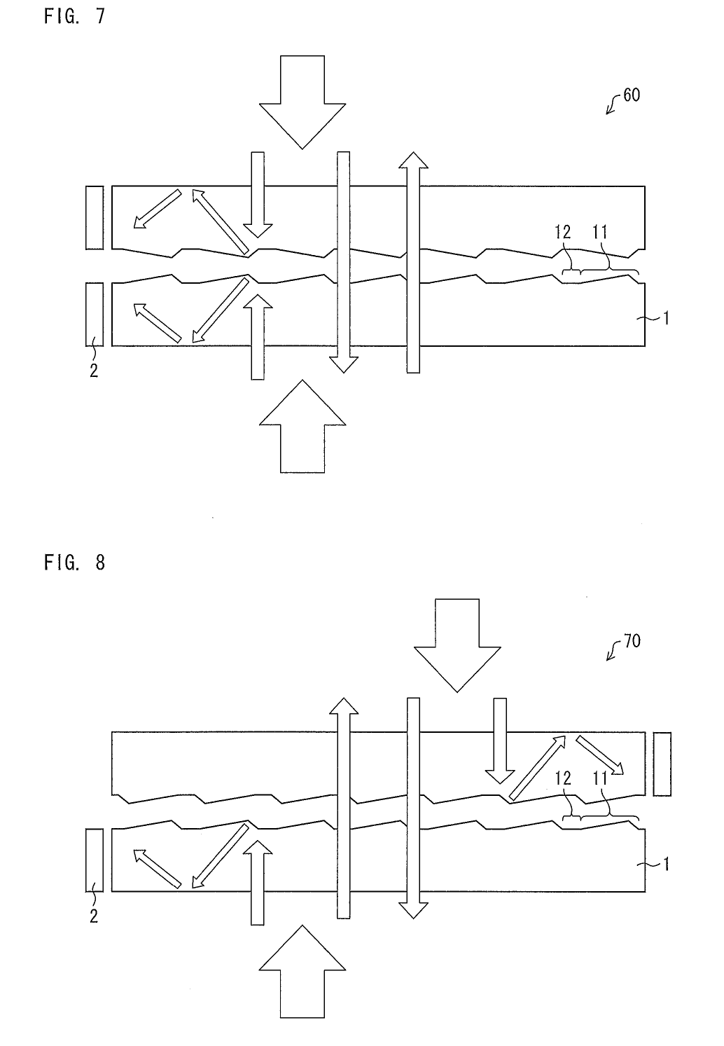

The following describes another embodiment of the solar cell module of the present invention, with reference to FIGS. 7 and 8. FIG. 7 is a cross-sectional view illustrating a solar cell module 60. FIG. 8 is a cross-sectional view illustrating a solar cell module 70. As illustrated in FIGS. 7 and 8, the solar cell modules 60 and 70 are different from the solar cell module 10 of Embodiment 1 in that two light guide plates 1 are provided, and the two light guide plates 1 are stacked so as to face each other. The present embodiment deals with only differences between the present embodiment and Embodiment 1, and omits to describe other details.

As illustrated in FIG. 7, the solar cell module 60 includes the two light guide plates 1 and two solar cell elements 2 which are provided so as to positionally correspond respectively to the two light guide plates 1. The two light guide plates 1 are stacked so that the back surface of one of the two light guide plates 1 faces the back surface of the other one of the two light guide plates 1. In the solar cell module 60, the two light guide plates 1 are stacked so that respective solar cell elements 2 of the two light guide plates 2 overlap each other when the two light guide plates 1 are viewed in a direction along a line penetrating the light entry surfaces and the back surfaces. The two light guide plates 1 of the solar cell module 60 can be stacked by a method such as bonding the two light guide plates 1 via an light transmissive adhesive or the like.

In the solar cell module 60, the two light guide plates 1 are stacked so that respective back surfaces face each other inward. This makes it possible to protect the traveling direction changing sections 11 and the transmission sections 12 which are provided on the back surfaces, and prevent a flaw thereof by contact or the like. Furthermore, light entering the two light guide plates 1 via respective light entry surfaces can be converged at the solar cell elements 2 so as to be utilized in generation of electricity. This makes it possible to utilize, in generation of electricity, light entering the solar cell module 60 from both sides thereof. The solar cell module 60 illustrated in FIG. 7 was made to see how much electricity is generated by the solar cell module 60. The result was approximately 42 W.

As is the case with the solar cell module 60, the solar cell module 70 illustrated in FIG. 8 includes two light guide plates 1 and two solar cell elements 2 which are provided so as to positionally correspond to the two light guide plates 1. The solar cell module 70 is different from the solar cell module 60 in that the light guide plates 1 are stacked so that respective solar cell elements are positioned diagonally. That is, the two solar cell elements 2 face diagonally with respect to a line penetrating the light entry surfaces and the back surfaces of the two light guide plates 1.

As is the case with the solar cell module 60, the solar cell module 70 makes it possible to protect the traveling direction changing sections 11 and the transmission sections 12 which are provided on the back surfaces, and prevent a flaw thereof by contact or the like. In addition, the solar cell module 70 makes it possible to utilize, in generation of electricity, light entering the solar cell module 70 from both sides thereof.

### Embodiment 6

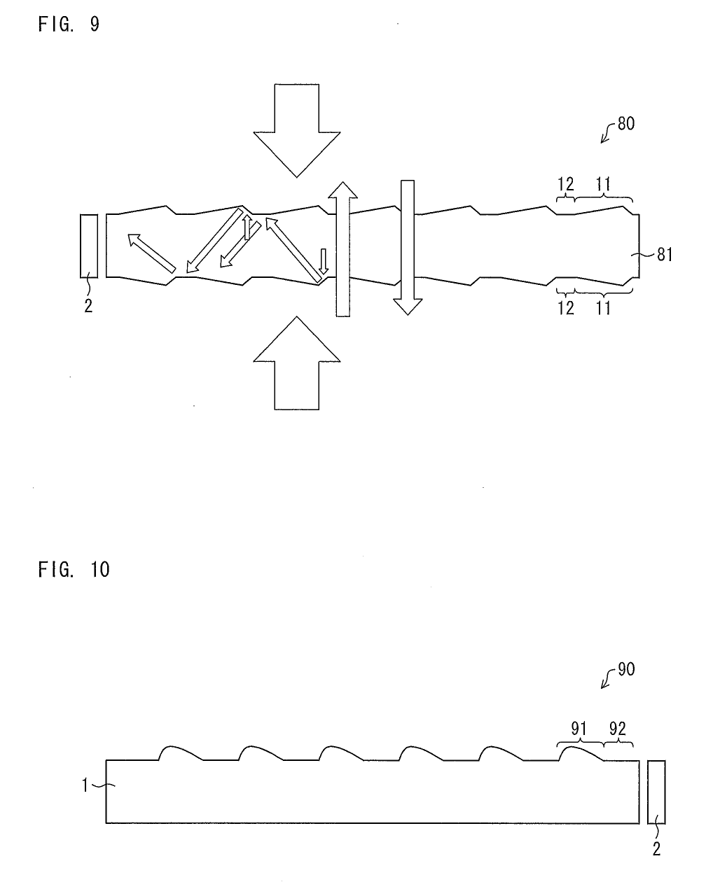

The following describes another embodiment of the solar cell module of the present invention, with reference to FIG. 9. FIG. 9 is a cross-sectional view illustrating a solar cell module 80. As illustrated in FIG. 9, the solar cell module 80 is different from the solar cell module 10 of Embodiment 1 in that traveling direction changing sections and transmission sections are provided on each of surfaces (a light entry surfaces and a back surface) intersecting with an intersecting surface on which a solar cell element 2 is provided. The present embodiment deals with only differences between the present embodiment and Embodiment 1, and omits to describe other details.

The solar cell module 80 is arranged such that traveling direction changing sections 11 and transmission sections 12 are provided on each of surfaces intersecting with an intersecting surface on which a solar cell element 2 is provided, namely, on each of the light entry surface and the back surface. On each of the light entry surface and the back surface, the traveling direction changing sections 11 are formed so that each of second inclined surfaces thereof is closer to the solar cell element 2 than a corresponding one of first inclined surfaces.

In the solar cell module 80, the traveling direction changing sections 11 and the transmission sections 12 are provided on each of the light entry surface and the back surface. This makes it possible to converge, at the solar cell element 2, light entering the solar cell module 80 from both sides thereof, so as to utilize the light in generation of electricity. This makes it possible to increase power generation efficiency. The solar cell module 90 illustrated in FIG. 9 was made to see how much electricity is generated by the solar cell module 80. The result was approximately 38 W.

The traveling direction changing sections 11 and the transmission sections 12 may also be formed so that the traveling direction changing sections 11 and the transmission sections 12 on one surface of the light guide plate 1 and those on the opposite surface look overlapped when the light guide plate 1 is viewed in a direction along a line penetrating the light entry surface and the back surface. This makes it possible to secure the transparency of the solar cell module 50. Alternatively, the traveling direction changing sections 11 and the transmission sections 12 may be formed so that the traveling direction changing sections 11 and the transmission sections 12 on one surface of the light guide plate 1 and those on the opposite surface look displaced when the light guide plate is viewed in a direction along a plane penetrating the light entry surface and the back surface. Accordingly, light totally reflected on both surfaces of the light guide plate 1 converges at the solar cell element 2. This increases power generation efficiency of the solar cell element 2.

### Embodiment 7

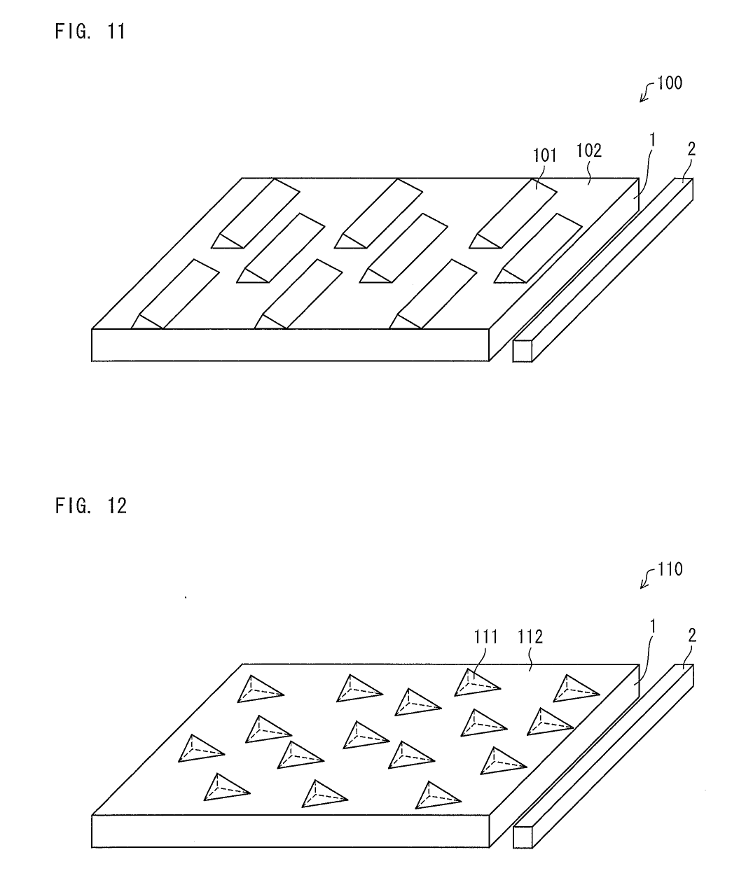

The following describes another form of traveling direction changing sections of a solar cell module of the present invention, with reference to FIGS. 10 through 12. FIG. 10 is a cross-sectional view illustrating a solar cell module of another embodiment of the present invention. FIG. 11 is a perspective view illustrating a solar cell module of another embodiment of the present invention. FIG. 12 is a perspective view illustrating a solar cell module of another embodiment of the present invention. As illustrated in FIGS. 10 through 12, solar cell modules 90, 100, and 110 are different from those of other embodiments in shape of the traveling direction changing sections. Accordingly, the present embodiment deals with only differences between the present embodiment and other embodiments, and omits to describe other details.

As illustrated in FIG. 10, each of traveling direction changing sections 91 provided on a back surface has an asymmetric cross-sectional shape along a plane perpendicular to the back surface and the intersecting surface, and a tip of the cross-sectional shape is round-shaped. Each of the transmission sections 92 is that area on the back surface in which no traveling direction changing section 91 is provided. Thus, a shape of each of the traveling direction changing sections 91 is not particularly limited at an intersecting point between a first inclined surface and a second inclined surface, provided that each of the traveling direction changing sections 91 has a first inclined surface and a second inclined surface. Specifically, the shape of each of the traveling direction changing sections 91 may be a taper shape or a shape like ‘R.’

As illustrated in FIG. 11, each of traveling direction changing sections 101 provided on the back surface of the solar cell module 100 has a triangular column shape, and such a plurality of triangular columns are randomly disposed on the back surface. Each of the traveling direction changing sections 101 has, along the intersecting surfaces, a length greater than a longer side of the intersecting surfaces. The transmission section 102 is that area on the back surface in which no traveling direction changing section 101 is provided. Thus, positions and disposition of the traveling direction changing sections 101 are not particularly limited, provided that each of the traveling direction changing sections 101 has a first inclined surface and a second inclined surface. Specifically, the traveling direction changing sections 101 may be disposed on the back surface in a stripe pattern, or may be randomly disposed.

As illustrated in FIG. 12, each of traveling direction changing sections 111 provided on the back surface of the solar cell module 110 has a shape of a triangular pyramid, and such a plurality of triangular pyramids are randomly disposed on the back surface. The transmission section 102 is that area on the back surface in which no traveling direction changing section 111 is provided. Thus, a shape of each of the traveling direction changing sections 111 is not particularly limited, provided that each of the traveling direction changing sections 111 has a first inclined surface and a second inclined surface. Specifically, each of the traveling direction changing sections 111 may have a triangular column shape extended in parallel with the intersecting surfaces, or may have a shape of a triangular pyramid.

### Embodiment 8

The following describes further another embodiment of the solar cell module of the present invention, with reference to FIG. 13. FIG. 13 is a cross-sectional view illustrating a solar cell module 200.

The solar cell module 200 includes a light guide plate 201 and a solar cell element 2. Provided on that back surface of the light guide plate 201 which is opposite to a surface (light entry surface) 212 that light L1 through L3 indicated by arrows enter are a plurality of traveling direction changing sections 211 for changing traveling directions of the light. The plurality of traveling direction changing sections 211 each have a triangular column shape and are parallelly provided with no space.

The solar cell module 200 can be taken as having the same arrangement as the solar cell module 10 of Embodiment 1 except that the transmission sections 12 (flat sections) are omitted, and only the traveling direction changing sections 11 (corresponding to the traveling direction changing sections 211 in FIG. 13) are provided in series. Accordingly, the present embodiment deals with only differences between the present embodiment and Embodiment 1 in detail.

Each of the traveling direction changing sections 211 is provided so that one side of its triangular column shape faces the light guide plate 201, and other two sides protrude outward with respect to the light guide plate 201. The other two side surfaces refer to (i) a first inclined surface 211a which reflects, toward the inside of the light guide plate 201, light which has entered via the light entry surface and (ii) a second inclined surface 211b inclined in a direction opposite to a direction in which the first inclined surface 211a is inclined.

An angle θB which is formed between the second inclined surface 211b and the back surface is smaller than an angle θA which is formed between the first inclined surface 211a and the back surface. Each of the angles θA and θB is preferably smaller than 90°, namely, an acute angle. The back surface which is opposite to the light entry surface 212 refers to a horizontal plane (a plane indicated by a dashed-dotted line in FIG. 13) which is assumed to exist in a case where the traveling direction changing sections 211 each having a triangular column shape are not provided.

The solar cell element 2 is provided on, out of those intersecting surfaces (end faces) of the light guide plate 201 which intersect with the light entry surface 212, an intersecting surface 213 which is located on a second inclined surface 211b side with respect to an adjacent first inclined surface 211a when a first inclined surface 211a and an adjacent second inclined surface 211b which constitute one traveling direction changing section 211 are taken as a reference position. That is, the solar cell element 2 is provided on an end face located in a direction in which incident light reflected on the first inclined surfaces 211a propagates.

In the solar cell module 200, external light (light L1) which is incident upon a first inclined surface 211a via the light entry surface 212 is substantially totally reflected on the first inclined surface 211a so as to propagate inside the light guide plate 201 toward the intersecting surface 213. The light reflected on the first inclined surface 211a toward the inside of the light guide plate 201 is repeatedly reflected between the light entry surface 312 and mainly the second inclined surfaces 211b while propagating to the intersecting surface 213. This occurs in the same manner as Embodiments 1 through 7. On the other hand, a large part of external light (light L2 and L3) which is incident upon a second inclined surface 211b via the light entry surface 212 passes through the light guide plate 201 for the reason that an inclination angle (angle θB) of the second inclined surfaces 211b is relatively small.

As compared to the solar cell module 10 of Embodiment 1, the traveling direction changing sections 211 are provided at a higher density in the solar cell module 200. Therefore, in a case where the light guide plate 201 of the solar cell module 200 is used as, e.g., a window glass, the solar cell module 200 has much higher power generation efficiency (more correctly, light convergence efficiency) than the solar cell module 10 of Embodiment 1 has. On the other hand, light transmission from a light entry surface 212 side to a back surface side can be decreased, as compared to the solar cell module 10 of Embodiment 1. Such a characteristic of the solar cell module 200 is particularly suitable for a use such as a frosted glass window although there is no particular limitation in use.

Further, in a case where the solar cell module 200 is used as a window or the like, an angle θB of not greater than 10° makes it possible to secure more surely that optical transparency of the second inclined surfaces 211b which is sufficient from a practical viewpoint, although the angle θB is not particularly limited.

### Embodiment 9

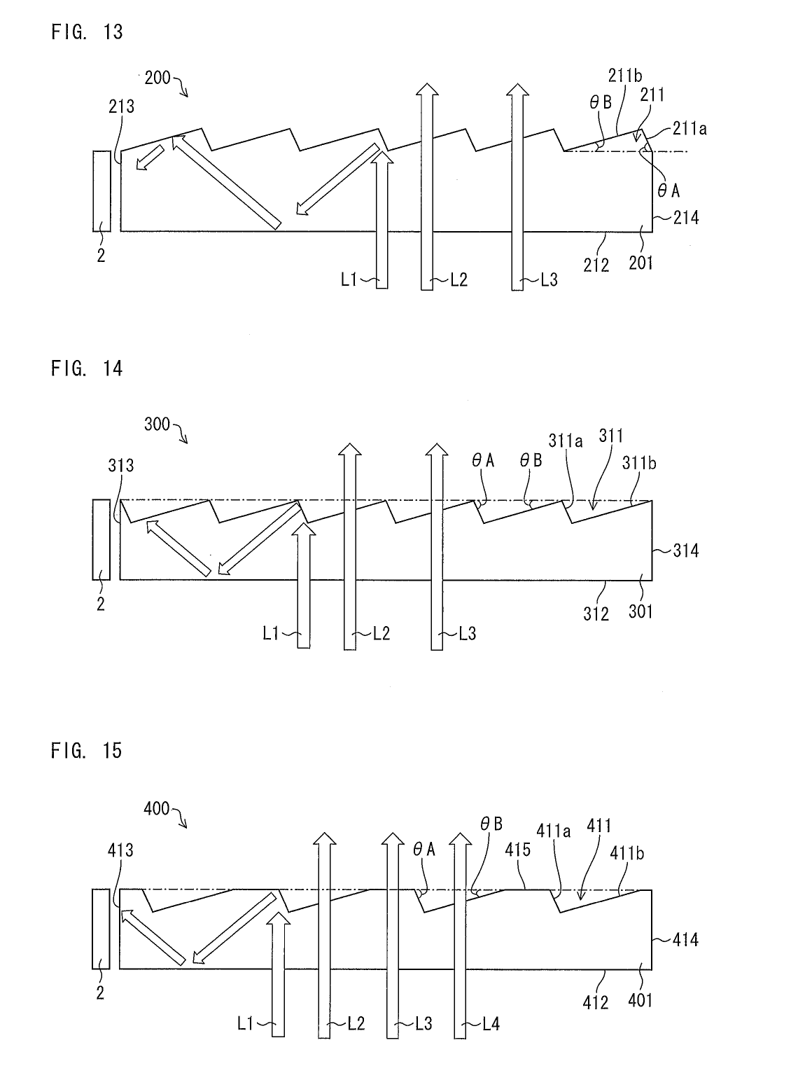

The following describes further another embodiment of the solar cell module of the present invention, with reference to FIG. 14. FIG. 14 is a cross-sectional view illustrating a solar cell module 300.

The solar cell module 300 is not substantially different from the solar cell module 200 of Embodiment 8, except that depressed traveling direction changing sections 311 are provided instead of the protruding traveling direction changing sections 211 (see FIG. 13). Accordingly, the present embodiment deals with only differences between the present embodiment and Embodiment 8 in detail.

The solar cell module 300 includes a light guide plate 301 and a solar cell element 2. Provided on that back surface of the light guide plate 301 which is opposite to an entry surface (light entry surface) 312 that light L1 through L3 indicated by arrows enter are a plurality of traveling direction changing sections 311 for changing traveling directions of the light. The plurality of traveling direction changing sections 311 are depressions shaped like triangular columns, and parallelly provided with no space.

Each of the traveling direction changing sections 311 is provided so that one side of its triangular column shape faces outward with respect to the light guide plate 301, and other two sides are disposed so as to be depressed toward the inside of the light guide plate 301. The other two sides are (i) a first inclined surface 311a which reflects, toward the inside of the light guide plate 301, light which has entered via the light entry surface and (ii) a second inclined surface 311b inclined in a direction opposite to a direction in which the first inclined surface 311a is inclined.

An angle θB which is formed between the second inclined surface 311b and the back surface is smaller than an angle θA which is formed between the first inclined surface 311a and the back surface. Each of the angles θA and θB is preferably smaller than 90°, namely, an acute angle. The back surface which is opposite to the light entry surface 312 refers to a horizontal plane (a plane indicated by a dashed-dotted line in FIG. 14) which is assumed to exist in a case where the traveling direction changing sections 311 each of which is a depression shaped like a triangular column are not provided.

The solar cell element 2 is provided on, out of those intersecting surfaces (end faces) of the light guide plate 301 which intersect with the light entry surface 312, an intersecting surface 313 which is located on a first inclined surface 311a side with respect to an adjacent second inclined surface 311b when a first inclined surface 311a and an adjacent second inclined surface 311b which constitute one traveling direction changing section 311 are taken as a reference position. That is, the solar cell element 2 is provided on an end face located in a direction in which incident light reflected on the first inclined surfaces 311a propagates.

The solar cell module 300 can be considered as having such an arrangement that a protruding structure having a first inclined surface 311a and a second inclined surface 311b is provided between two adjacent traveling direction changing sections 311. The protruding structure corresponds to each of the traveling direction changing sections 211 of the solar cell module 200 (see FIG. 13). Accordingly, the solar cell module 300 and the solar cell module 200 substantially have the same function. Therefore, refer to Embodiment 8 as appropriate for: movement of light L1 through L3 entering the solar cell module 300; a suitable use of the solar cell module 300; preferable values of the angles θA and θB; etc.

### Embodiment 10

The following describes further another embodiment of the solar cell module of the present invention, with reference to FIG. 15. FIG. 15 is a cross-sectional view illustrating a solar cell module 400.

The solar cell module 400 is not substantially different from the solar cell module 300 of Embodiment 9, except that depressed traveling direction changing sections 411 and flat transmission sections 415 are provided on a back surface which is opposite to a light entry surface. More specifically, in the solar cell module 300, the plurality of depressed traveling direction changing sections 311 are disposed parallelly and adjacently with no space. In contrast, in the solar cell module 400, the plurality of depressed traveling direction changing section 411 (corresponding to the traveling direction changing section 311) are disposed parallelly with a constant space. Such a constant space between two adjacent traveling direction changing sections 411 corresponds to a flat transmission section 415.

The present embodiment below deals with only differences between the present embodiment and Embodiment 9 in detail.

The solar cell module 400 includes a light guide plate 401 and a solar cell element 2. A plurality of traveling direction changing sections 411 and a plurality of transmission sections 415 are provided alternately on that back surface of the light guide plate 401 which is opposite to an entry surface (light entry surface) 412 that light L1 through L4 indicated by arrows enter.

Each of the traveling direction changing sections 411 is provided so that one side of its triangular column shape faces outward with respect to the light guide plate 401, and other two sides are disposed so as to be depressed toward the inside of the light guide plate 401. The other two side surfaces refer to (i) a first inclined surface 411a which reflects, toward the inside of the light guide plate 401, light which has entered via the light entry surface and (ii) a second inclined surface 411b inclined in a direction opposite to a direction in which the first inclined surface 411a is inclined.

An angle θB which is formed between the second inclined surface 411b and the back surface is smaller than an angle θA which is formed between the first inclined surface 411a and the back surface. Each of the angles θA and θB is preferably smaller than 90°, namely, an acute angle. Refer to Embodiment 8 for particularly preferable values of the angles θA and θB, etc. The back surface which is opposite to the light entry surface 412 refers to a horizontal plane which is assumed to exist in a case where the traveling direction changing sections 311 each of which is a depression shaped like a triangular column are not provided, i.e., refers to a horizontal plane where the transmission sections 415 are provided (a plane indicated by a dashed-dotted line in FIG. 15).

The solar cell element 2 is provided on, out of those intersecting surfaces (end faces) of the light guide plate 401 which intersect with the light entry surface 412, an intersecting surface 413 which is located on a first inclined surface 411a side with respect to an adjacent second inclined surface 411b when a first inclined surface 411a and an adjacent second inclined surface 411b which constitute one traveling direction changing section 411 are taken as positional references. That is, the solar cell element 2 is provided on an end face located in a direction in which incident light reflected on the first inclined surfaces 411a propagates.

Among the light L1 through L4 which have entered the solar cell module 400, the light L1 incident upon a first inclined surface 411a is substantially totally reflected on the first inclined surface 411a so as to propagate inside the light guide plate 401 to enter the solar cell element 2. A large part of the light L2 and L4 which are incident upon second inclined surfaces 411b passes through the light guide plate 401 to exit therefrom to a back surface side. The light L3 incident upon a transmission section 415 substantially mostly passes through the light guide plate 401 to exit therefrom to the back surface side.

Thus, the light guide plate 401 of the solar cell module 400 of the present embodiment has optical transparency comparable to the light guide plate of the solar cell module 10 of Embodiment 1. This makes it possible to suitably use the solar cell module 400 as, e.g., windows of a building, a conveyance, etc. The “window” refers to such one that the light guide plate of the solar cell module of the present invention is utilized as its window pane, and refers to both a fixed (i.e., cannot be opened nor closed) window and an openable and closable window. Where to install such a window is not particularly limited. For example, the “window” refers to a window installed on a wall surface of a building, a skylight, and other various types of windows. The window may be one with or without a window frame.

In any of the solar cell modules of Embodiments 1 through 7, a large part of external light incident upon a second inclined surface which is less steep (e.g., a second inclined surface 11b in FIG. 3) passes through the light guide plate, as is the case with the solar cell modules of Embodiments 8 through 10.

As described above, a solar cell module of the present invention may include; a light guide plate having, on its back surface which is opposite to its light entry surface, traveling direction changing sections for changing a traveling direction of light incident via the light entry surface; and a solar cell element being provided on one of intersecting surfaces which intersects with the light entry surface of said light guide plate, the traveling direction changing sections each being a protruding or depressed structure having (i) a first inclined surface for reflecting the light incident via the light entry surface and (ii) a second inclined surface which forms an angle with the back surface, the angle is smaller than an angle formed between the first inclined surface and the back surface, and the one of the intersecting surfaces on which said solar cell element is provided is one of the intersecting surfaces to which the light reflected on the first inclined surface travels to reach.

In the arrangement above, the solar cell module of the present invention is preferably arranged such that: in a case where each of the traveling direction changing sections is the protruding structure, said solar cell element is provided on one of the intersecting surfaces which one of the intersecting surfaces is located on a second inclined surface side with respect to the first inclined surface; and in a case where each of the traveling direction changing sections is the depressed structure, said solar cell element is provided on one of the intersecting surfaces which one of the intersecting surfaces is located on a first inclined surface side with respect to the second inclined surface.

In the arrangement above, the solar cell module of the present invention is preferably arranged such that: said light guide plate has, on its back surface which is opposite to its light entry surface, transmission sections for allowing the light incident via the light entry surface to pass through, and the traveling direction changing sections.

According to the arrangement, the light which has entered a traveling direction changing section is reflected on its first inclined surface so as to converge at the solar cell element. This makes it possible to converge, at the solar cell element, more light entering the light guide plate. As a result, power generation efficiency is increased. Further, light incident upon a transmission section via the light entry surface passes therethrough. This makes it possible to maintain the transparency of the light guide plate. This makes it possible to realize a transparent solar cell module which can efficiently generate electricity. Such a transparent solar cell module can be attached to, e.g., an existing window frame so as to be suitably used as a window glass. In addition, there is no need to add a fluorescent material or the like to the light guide plate. This makes it possible to manufacture the solar cell module inexpensively and easily.

Further, the solar cell module of the present invention is preferably arranged such that: each of the traveling direction changing sections has a triangular cross-sectional shape along a plane which intersects with the intersecting surface on which said solar cell element is provided which plane is perpendicular to the back surface and the intersecting surfaces. This makes it possible to efficiently converge, at the solar cell element, light incident upon the traveling direction changing sections.

The solar cell module of the present invention is preferably arranged such that: the traveling direction changing sections is formed as at least a surface of a film provided on the back surface. Further, the solar cell module of the present invention is preferably arranged such that: the traveling direction changing sections and the transmission sections are formed as at least a surface of a film provided on the back surface.

Thus, the solar cell module is manufactured by attaching, to the substrate, the film having the shapes of the traveling direction changing sections or the film having the shapes of the traveling direction changing sections and the transmission sections. This makes it possible to manufacture the solar cell module more easily. In addition, there is no need to form the traveling direction changing sections and the transmission sections on the light guide plate in advance. This makes it possible to easily apply an existing window glass or the like to the solar cell module.

Further, the solar cell module of the present invention preferably further includes: a light transmissive substrate stacked on the back surface so as to face thereto. This makes it possible to protect the traveling direction changing sections and the transmission sections which are provided on the light guide plate, and prevent a flaw thereof by contact or the like. This also makes it possible to use the solar cell module as a double-glazed glass.

Further, the solar cell module of the present invention preferably includes: a plurality of the light guide plates, the light guide plates being stacked and being adjacent to each other such that the back surfaces thereof and the light entry surfaces thereof face each other. This makes it possible to increase power generation efficiency without increasing installation area.

Further, the solar cell module of the present invention is preferably arranged such that: the light guide plates thus stacked are identical with each other as to where the traveling direction changing sections are positioned. Alternatively, the solar cell module of the present invention is preferably arranged such that: the light guide plates thus stacked are identical with each other as to where the traveling direction changing sections and the transmission sections are positioned. This makes it possible to realize a solar cell module with a high transparency.

Further, the solar cell module of the present invention is preferably arranged such that: the light guide plates thus stacked are not common with each other as to where the traveling direction changing sections are positioned. Alternatively, the solar cell module of the present invention is preferably arranged such that: the light guide plates thus stacked are not common with each other as to where the traveling direction changing sections and the transmission sections are positioned. This makes it possible to further increase power generation efficiency.

Further, the solar cell module of the present invention preferably includes: two of said light guide plates, said two light guide plates being stacked so that the back surface of one of the two light guide plates faces the back surface of the other one of the two light guide plates. This makes it possible to protect the traveling direction changing sections and the transmission sections which are provided on the light guide plate, and prevent a flaw thereof by contact or the like. This also makes it possible to use the solar cell module as a double-glazed glass. This makes it possible to converge, at the solar cell element, light entering the solar cell module from both sides thereof, so as to utilize the light in generation of electricity. This makes it possible to increase power generation efficiency.

Further, the solar cell module of the present invention is preferably arranged such that: said light guide plate further has traveling direction changing sections on the light entry surface. The solar cell module of the present invention is preferably arranged such that: said light guide plate further has traveling direction changing sections and transmission sections on the light entry surface. This makes it possible to converge, at the solar cell element, light entering the solar cell module from both sides thereof, so as to utilize the light in generation of electricity. This makes it possible to increase power generation efficiency.

The solar cell module of the present invention may be arranged such that: the transmission sections are a part of the back surface or each have a flat plane parallel with the back surface.

Further, the solar cell module of the present invention may be arranged such that: the transmission sections are a part of the light entry surface or each have a flat plane parallel with the light entry surface.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The present invention makes it possible to provide a transparent solar cell module which is high in design freedom, and inexpensive and easy to manufacture. Therefore, the transparent solar cell module can be suitably utilized as a photovoltaic power system in a window of a building or an automobile, or a photovoltaic power system on a roof of a building.

### REFERENCE SIGNS LIST

1 Light guide plate
2 Solar cell element
10 Solar cell module
11 Traveling direction changing section
11a First inclined surface
11b Second inclined surface
12 Transmission section
30 Solar cell module
31 Traveling direction changing section
32 Transmission section
40 Solar cell module
41 Light transmissive substrate
50 Solar cell module
60 Solar cell module
80 Solar cell module
90 Solar cell module
91 Traveling direction changing section
92 Transmission section
100 Solar cell module
101 Traveling direction changing section
102 Transmission section
110 Solar cell module
111 Traveling direction changing section
112 Transmission section
200 Solar cell module
201 Light guide plate
211 Traveling direction changing section
211a First inclined surface
211b Second inclined surface
212 Light entry surface(light entry surface)
213 Intersecting surface
300 Solar cell module
301 Light guide plate
311 Traveling direction changing section
311a First inclined surface
311b Second inclined surface
312 Light entry surface (light entry surface)
313 Intersecting surface
400 Solar cell module
401 Light guide plate
411 Traveling direction changing section
411a First inclined surface
411b Second inclined surface
412 Light entry surface(light entry surface)
413 Intersecting surface
415 Transmission section

1. A solar cell module comprising:
a light guide plate having, on its back surface which is opposite to its light entry surface, traveling direction changing sections for changing a traveling direction of light incident via the light entry surface; and
a solar cell element being provided on one of intersecting surfaces which intersects with the light entry surface of said light guide plate,
the traveling direction changing sections each being a protruding or depressed structure having (i) a first inclined surface for reflecting the light incident via the light entry surface and (ii) a second inclined surface which forms an angle with the back surface, the angle is smaller than an angle formed between the first inclined surface and the back surface, and
the one of the intersecting surfaces on which said solar cell element is provided is one of the intersecting surfaces to which the light reflected on the first inclined surface travels to reach.

2. The solar cell module as set forth in claim 1, wherein:
in a case where each of the traveling direction changing sections is the protruding structure, said solar cell element is provided on one of the intersecting surfaces which one of the intersecting surfaces is located on a second inclined surface side with respect to the first inclined surface; and
in a case where each of the traveling direction changing sections is the depressed structure, said solar cell element is provided on one of the intersecting surfaces which one of the intersecting surfaces is located on a first inclined surface side with respect to the second inclined surface.

3. The solar cell module as set forth in claim 1, wherein:
said light guide plate has, on its back surface which is opposite to its light entry surface, transmission sections for allowing the light incident via the light entry surface to pass through, and the traveling direction changing sections.

4. The solar cell module as set forth in claim 1, wherein:
each of the traveling direction changing sections has a triangular cross-sectional shape along a plane which intersects with the intersecting surface on which said solar cell element is provided which plane is perpendicular to the back surface and the intersecting surfaces.

5. The solar cell module as set forth in claim 1, wherein:
the traveling direction changing sections is formed as at least a surface of a film provided on the back surface.

6. The solar cell module as set forth in claim 3, wherein:
the traveling direction changing sections and the transmission sections are formed as at least a surface of a film provided on the back surface.

7. The solar cell module as set forth in claim 1, further comprising: a light transmissive substrate stacked on the back surface so as to face thereto.

8. The solar cell module as set forth in claim 1, comprising:
a plurality of the light guide plates,
the light guide plates being stacked and being adjacent to each other such that the back surfaces thereof and the light entry surfaces thereof face each other.

9. The solar cell module as set forth in claim 8, wherein:
the light guide plates thus stacked are identical with each other as to where the traveling direction changing sections are positioned.

10. The solar cell module as set forth in claim 3, comprising:
a plurality of the light guide plates,
the light guide plates being stacked and being adjacent to each other such that the back surfaces thereof and the light entry surfaces thereof face each other,
the light guide plates thus stacked being identical with each other as to where the traveling direction changing sections and the transmission sections are positioned.

11. The solar cell module as set forth in claim 8, wherein:
the light guide plates thus stacked are not common with each other as to where the traveling direction changing sections are positioned.

12. The solar cell module as set forth in claim 3, comprising:
a plurality of the light guide plates,
the light guide plates being stacked and being adjacent to each other such that the back surfaces thereof and the light entry surfaces thereof face each other,
the light guide plates thus stacked being not common with each other as to where the traveling direction changing sections and the transmission sections are positioned.

13. The solar cell module as set forth in claim 1, comprising:
two of said light guide plates,
said two light guide plates being stacked so that the back surface of one of the two light guide plates faces the back surface of the other one of the two light guide plates.

14. The solar cell module as set forth in claim 1, wherein said light guide plate further has traveling direction changing sections on the light entry surface.

15. The solar cell module as set forth in claim 3, wherein said light guide plate further has traveling direction changing sections and transmission sections on the light entry surface.

16. The solar cell module as set forth in claim 3, wherein:
the transmission sections are a part of the back surface or each have a flat plane parallel with the back surface.

17. The solar cell module as set forth in claim 15, wherein:
the transmission sections are a part of the light entry surface or each have a flat plane parallel with the light entry surface.

18. A solar power generating apparatus comprising:
a solar cell module recited in claim 1.

19. A window comprising:
as a window pane, a light guide plate of a solar cell module recited in claim 1.
